(19) United States
(12) Patent Application Publication
(10) Pub. No.: US 2018/0288899 A1
(43) Pub. Date: Oct. 4, 2018

(54) Protective Housing For An Electronic Module and Assembly Method

(71) Applicant: FRIWO Geratebau GmbH, Ostbevern (DE)

(72) Inventors: Linzhong Xu, Greven (DE); Taner Yilmaz, Munster (DE)

(73) Assignee: FRIWO Geratebau GmbH, Ostbevern (DE)

(21) Appl. No.: 15/938,563

(22) Filed: Mar. 28, 2018

(30) Foreign Application Priority Data
Mar. 28, 2017 (EP) 17163348.0

(51) Int. Cl. H05K 7/20; H05K 5/03; H05K 5/02; H05K 5/06

(52) U.S. Cl. CPC H05K 7/209; H05K 7/20436; H05K 5/064; H05K 5/0247; H05K 5/03

(57) ABSTRACT

A protective housing for an electronic module comprises a shell defining an inner compartment receiving an electrical component and a cooling element. The cooling element has a cover plate, a first side plate, and a second side plate. The first side plate and the second side plate extend from the cover plate, face each other, and form an inside surface, an outside surface, and edges of the cooling element. A portion of the inside surface of the cooling element covers the shell to form a cover of the inner compartment. The cooling element forms a channel that extends partly in the cover plate between opposing edges of the cooling element and increases a volume of the inner compartment. The inner compartment is filled with an electrically insulating material through a cut-out in the cover plate, leaving a void in a portion of the channel.

### CROSS-REFERENCE TO RELATED APPLICATION

This application claims the benefit of the filing date under 35 U.S.C. § 119(a)-(d) of European Patent Application No. 17163348.0, filed on Mar. 28, 2017.

### FIELD OF THE INVENTION

The present invention relates to an electronic module and, more particularly, to a protective housing for an electronic module.

### BACKGROUND

Power electronics control and convert electric power using electrical components such as solid-state electronics. It is necessary for certain applications, for example in powering portable devices, that the power electronics are compactly assembled. The tightly packed electronics, however, require electrically insulating protection while also increasing cooling needs.

Additionally, for outdoor applications, the power electronics must be safely operated in dusty and moist environments. A known Ingress Protection (“IP”) code relates to protection against solid particles and liquid ingression. A housing can be dust tight (IP6x) and provide protection against temporary submersion (IPx7) according to the Standard DIN EN 60529.

In order to seal a casing for power electronics in accordance with protection classes IPx6and IPx7, European Patent No. 2227929 B1 discloses a cup accommodating an electronic unit, the cup filled with a filling material and covered with a cooling element. Manufacturing of the cup and required elements to seal the power electronics, however, is complicated and therefore expensive. Further, the cup has relatively large overall dimensions and the cooling element is inefficient for some applications.

### SUMMARY

A protective housing for an electronic module comprises a shell defining an inner compartment receiving an electrical component and a cooling element. The cooling element has a cover plate, a first side plate, and a second side plate. The first side plate and the second side plate extend from the cover plate, face each other, and form an inside surface, an outside surface, and edges of the cooling element. A portion of the inside surface of the cooling element covers the shell to form a cover of the inner compartment. The cooling element forms a channel that extends partly in the cover plate between opposing edges of the cooling element and increases a volume of the inner compartment. The inner compartment is filled with an electrically insulating material through a cut-out in the cover plate, leaving a void in a portion of the channel.

### BRIEF DESCRIPTION OF THE DRAWINGS

The invention will now be described by way of example with reference to the accompanying Figures, of which:

FIG. 1 is an exploded perspective view of a power electronic unit;

FIG. 2 is a perspective view of the power electronic unit;

FIG. 3 is a sectional side view of the power electronic unit taken along line of FIG. 4;

FIG. 4 is a plan view of the power electronic unit;

FIG. 5 is a sectional view of the power electronic unit taken along line V-V of FIG. 3; and

FIG. 6 is a detail view of a region VI of the power electronic unit of FIG. 5.

### DETAILED DESCRIPTION OF THE EMBODIMENT(S)

Embodiments of the present invention will be described hereinafter in detail with reference to the attached drawings, wherein like reference numerals refer to the like elements. The present invention may, however, be embodied in many different forms and should not be construed as being limited to the embodiments set forth herein; rather, these embodiments are provided so that the disclosure will be thorough and complete and will fully convey the concept of the invention to those skilled in the art.

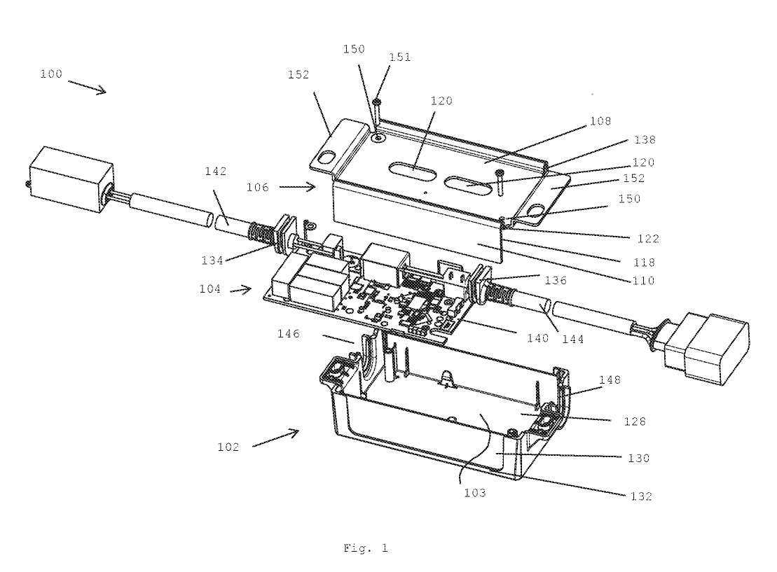

A power electronic unit 100 according to an embodiment is shown in FIG. 1.

The power electronic unit 100 includes an electrical component 104 as shown in FIG. 1. The electrical component 104 has a plurality of active electronic devices, such as diodes and transistors, assembled on a printed circuit board (PCB) 140. In various embodiments, the electrical component 104 may be any kind of power conversion system, such as a converter (e.g. DC-to-DC or AC-to-AC) or a rectifier (e.g. AC-to-DC or DC-to-AC) for converting an input power to an output power. The electrical component 104 has a primary sided input cable 142 that can be connected to an input terminal. On a secondary side, a power consumer can be connected to the electrical component 104 via an output cable 144. The cables 142, 144 are shown with kink protection elements in FIG. 1. The kink protection elements prevent the cables 142, 144 from being bent too sharply at a plurality of plugs 134, 136 of the electrical component 104.

The electrical component 104, as shown in FIG. 1, is disposed inside a shell 102 of the power electronic unit 100. In an embodiment, the shell 102 is formed by injection molding an electrically insulating plastic material into a one side open box. The shell 102 has a base 128 and a side wall 130. The base 128 has an essentially rectangular cross-section defining with the side wall 130 an inner compartment 103 for receiving the electrical component 104. In other embodiment, any other suitable cross-section, for example, a circular, elliptical, or any other polygonal cross-section, can be chosen for the base 128. The shell 102 forms an almost completely closed one side open box with a first and a second opening 146, 148 at its first and second end.

The first and second openings 146, 148 are closed by the plugs 136, 138 which form first and second passageways receiving the input and output cable 142, 144. Each plug 136, 138 may have an outline shape that fits into the openings 146, 148 and has a notch for partly receiving the side wall 130. In the embodiment shown in FIG. 1, each plug 136, 138 is formed from an electrically insulating, flexible, plastic material and has the shape of a one-sided rounded rectangle. In other embodiments, each plug 136, 138 could have any other suitable cross-section, for example, a circular, elliptical, or any other polygonal cross-section. In an embodiment, the plugs 136, 138 each include a kink protection element. In other embodiments, the plugs 134, 136 may be arranged differently.

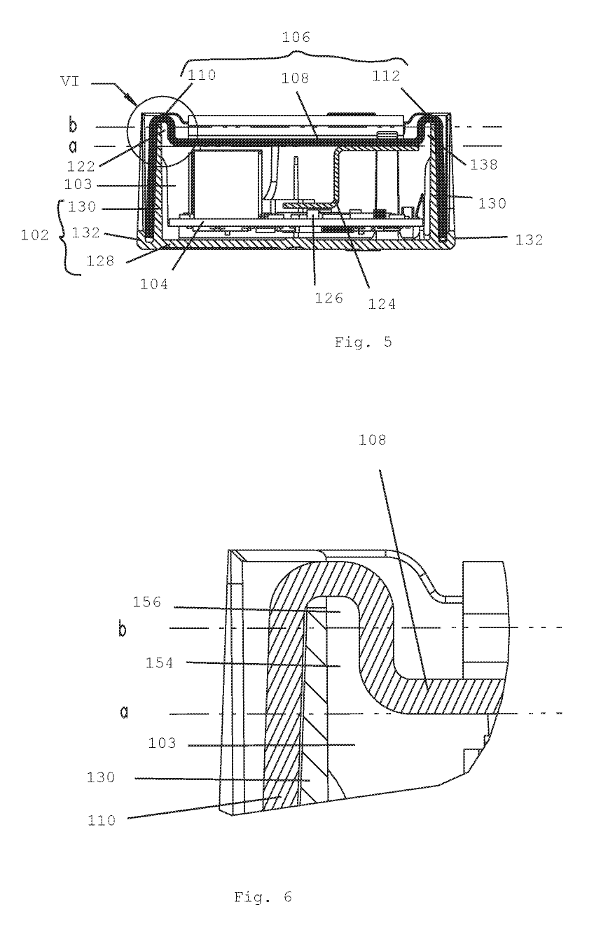

The shell 102, as shown in FIGS. 1 and 5, has notches 132 arranged at an outer periphery of the shell 102. The notches 132 extend along the edges of the base 128 and the side walls 130. These notches 132 are for attaching side plates 110, 112 of a cooling element 106 to the shell 102.

The cooling element 106 forms a cover for the shell 102 as shown in FIG. 1. In an embodiment, the cooling element 106 is produced by stamping and bending a single piece of a metal sheet. The cooling element 106 has a U-shaped cross-section with a cover plate 108, a first side plate 110, and a second side plate 112. In an embodiment, the cooling element 106 is made of a light weight material with a high thermal conductivity, such as aluminum. In an embodiment, the cooling element 106 has a coating which increases the thermal radiation power of the cooling element 106. Such a coating may, for example, be any black colored painting or black colored lacquer.

The assembled cooling element 106 and shell 102 form a protective housing 102, 106 of the power electronic unit 100. The protective housing 102, 106 has a rectangular geometry in the shown embodiments. However, as would be clear to one with ordinary skill in the art, the protective housing 102, 106 could have any other geometry in other embodiments.

At the edge between the cover plate 108 and the side plate 110, 112, the cooling element 106 forms two channels 122, 138 as shown in FIGS. 1, 5, and 6. The channels 122, 138 are disposed on opposing edges of the cover plate 108. The channels 122, 138, as shown in FIGS. 5 and 6, are bulges in the cover plate 108 with one side of the channels 122, 138 being formed by the side plate 110, 112 of the cooling element 106. In other embodiments, the cooling element 106 may have a single channel or any other number of channels in the cover plate 108 to connect opposing edges 118 of the cover plate 108. In further embodiments, the channels 122, 138 need not necessarily be parallel to the side plates 110, 112; the channels 122, 138 may be disposed diagonally in the cover plate 108.

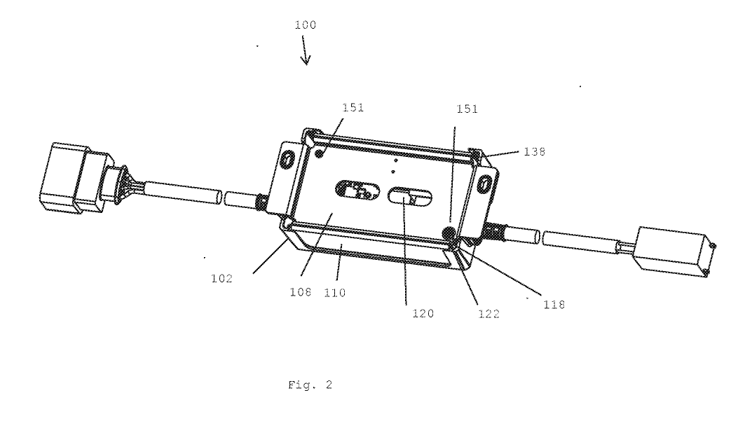

The cover plate 108 has at least one cut-out 120 as shown in FIG. 1. The assembled protective housing 102, 106, as shown in FIG. 2, is filled through the cut-outs 120 with a filling material.

The cover plate 108, as shown in FIG. 1, has a plurality of fastening passageways 150 receiving a fastener 151. Additionally, fastening plates 152 may be attached to the cover plate 108 for mechanically attaching the cover plate 108 to the side wall 130 of the shell 102.

The assembled power electronic unit 100 is shown in FIGS. 2-6.

As shown in FIG. 2, the cooling element 106 covers the shell 102. The end regions of the first side plate 110 and the second side plate 112 are received in the notches 132 of the shell 102 and clamped with the shell 102. In an embodiment, the cooling element 106 is attached to the base 128 of shell 102 by fasteners 151 extending through the cover plate 108. The fastening plates 152 of the cooling element 106 may, for example adhesively, be attached to the side wall 130 of the shell 102. The side plates 110, 112 of the cooling element 106, which are made of a material with high thermal conductivity, cover the side wall 130 of the shell 102, which is made of an electrically insulating material. The side plates 110, 112 are thermally connected to the cover plate 108, and thus, the surface for heat dissipation of the cooling element 106 is increased. Further, in another embodiment, ribs may be formed on the cooling element 106 and/or a coating with particles can further increase the surface of the cooling element 106, and thus, increase the heat dissipation rate. Consequently, the power electronic unit 100 can be cooled by the cooling element 106 more efficiently.

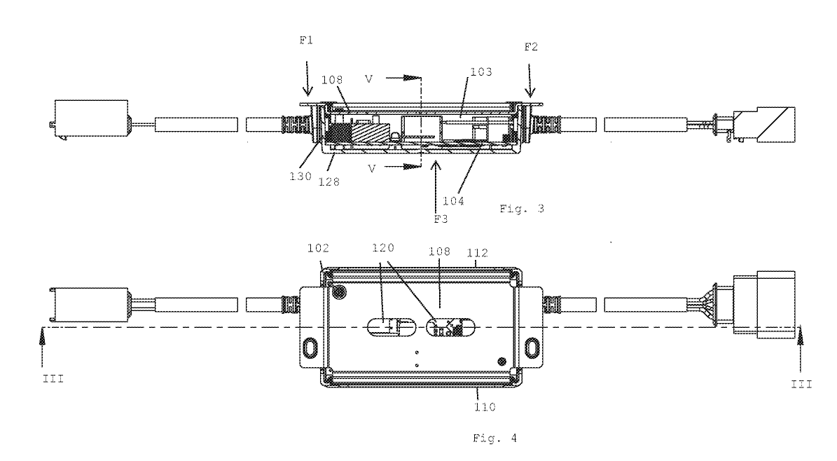

In the assembled state, as shown in FIGS. 3 and 4, the electrical component 104 is placed on the base 128 of the shell 102. The shell 102 is covered by the cover plate 108 of the cooling element 106. As shown in FIG. 5, the side plates 110, 112 of the cooling element 106 are partly inserted into the notches 132 and the side wall 130 of the shell 102 is partly inserted into the channels 122, 138 formed in the cooling element 106.

The remaining inner compartment 103 is filled with an electrically insulating filling material through the cut-outs 120. In an embodiment, the filling material is an electrically insulating, flame protective casting resin. In other embodiments, the filling material may comprise any suitable casting resin, for instance, an epoxy resin or a silicon material. The filling material seals and electrically insulates the electronic component 104, and the electronic components 104 can be packed more densely. Further, the protective housing 102, 106 is waterproofed and not affected by external jolts, vibrations, and shocks.

In an embodiment shown in FIG. 5, the electrical component 104 has a heat coupling element 126. The heat coupling element 126 is connected thermally to the cooling element 106 by a heat transfer element 124. The heat transfer element 124 is made of a material with high thermal conductivity, for example, a metal as aluminum. Generally, the thermal conductivity of the heat transfer element 124 is higher than the thermal conductivity of the filling material and the thermal conductivity of the shell 102. Thus, heat generated by the electrical component 104 can be transported efficiently to the cooling element 106, efficiently distributed in the cooling element 106, which is also made of a material with a high thermal conductivity, and efficiently dissipated to the exterior from the cooling element 106.

Two fillings levels a and b of the filling material are shown in FIGS. 5 and 6. These filling levels a, b and the inner surface of the channel 122 define a lower channel space 154 and an upper channel space 156. In an embodiment, the inner compartment 103 of the power electronic unit 100 is filled with a filling material leaving a void 154, 156 in the channels 122, 138, corresponding to the filling level a. In an alternative embodiment, in addition to the inner compartment 103, the channels 122, 138 are partly filled with the filling material, corresponding to the filling level b and leaving void 156 in the channels 122, 138. When the filling material is cured and the protective housing 102, 106 is assembled, the void 154, 156 in the channels 122, 138 may be connected to a cooling fluid, and thus, the cooling efficiency can be further increased.

A process for assembling the power electronic unit 100 will now be described in greater detail with reference to FIGS. 1-6.

In a first step, the PCB 140 is assembled with electronic components for converting or controlling electrical power to form the electrical component 104.

Next, at least one plug 134, 136 is assembled at the electrical component 104. Each plug 134, 136 comprises one cable 142, 144, which is connected to the PCB 140.

The electrical component 104 is then inserted in the shell 102 and connected to the electrically insulating base 128. The plug 134, 136 forms a part of the side wall 130 so that the shell 102 has essentially the geometry of a one-side open box.

In a next step, the cooling element 106 is attached to the shell 102 forming an inner compartment 103. The heat transfer element 124 is inserted and attached to the heat coupling element 126 and the cooling element 106. In an embodiment, the heat transfer element 124 is clamped, soldered, or bonded to the heat coupling element 126 and the cooling element 106. In an embodiment, the cover plate 108 of the cooling element 106 is attached to the base 128 of the shell 102 by the fastener 151. In another embodiment, the fastening plates 152 are connected to the cover plate 108 and are attached, for example, adhesively or by a fastener to the side wall 130 of the shell 102.

In a final step, a filling material is filled into the inner compartment 103 through cut-outs 120. The dash-dotted line a in FIG. 5 and FIG. 6 indicates the filling level. The air enclosed in the inner compartment 103 escapes via the channels 122, 138. When the filling material is cured, the inner compartment 103 is sealed with an electrically insulating material leaving a void 154, 156 in the channels 122, 138. Thus, the electrical component 104 is sealed and mechanically fixed to the shell 102.

In another embodiment without fasteners, the power electronic unit 100 is clamped during the final filling step. As shown in FIG. 3, forces F1 and F2 are applied to the fastening plates 152 and force F3 is applied to the base 128 in an opposing direction to the forces F1 and F2 to clamp the shell 102 and the cooling element 106. In another embodiment, at least one side plate 110, 112 of the cooling device 106 partly extends into at least one notch 132 of the base 128 to clamp the cooling device 106 to the shell 102.

In the embodiment without fasteners, the filling material is filled into the inner compartment 103 through cut-outs 120 to the level of the dash-dotted line b in FIG. 5 and FIG. 6. The air enclosed in the inner compartment 103 escapes via the channels 122, 138. When the filling material is cured, the inner compartment 103 and part of the channels 122, 138 are sealed with an electrically insulating material, leaving a void 156 in the channels 122, 138. Even if the forces F1, F2, and F3 are no longer applied, the cured filling material adhesively connects the cooling element 106 to the shell 102. Thus, additional fastening can be avoided. However, as would be understood by one with ordinary skill in the art, fasteners could also be applied.

The power electronic unit 100 is sealed against water and dust, and thus, meets the requirements of IP67 and all relevant electric safety standards. Moreover, the electrical components 104 can be densely packed and the generated heat is dissipated efficiently by the protective housing 102, 106.

What is claimed is:

1. A protective housing, comprising:
a shell defining an inner compartment receiving an electrical component; and
a cooling element having a cover plate, a first side plate, and a second side plate, the first side plate and the second side plate extending from the cover plate, facing each other, and forming an inside surface, an outside surface, and edges of the cooling element, a portion of the inside surface of the cooling element covers the shell to form a cover of the inner compartment, the cooling element forms a first channel that extends partly in the cover plate between opposing edges of the cooling element and increases a volume of the inner compartment, the inner compartment is filled with an electrically insulating material through a cut-out in the cover plate leaving a void in a portion of the first channel.

2. The protective housing of claim 1, further comprising a heat transfer element and a heat coupling element connected to the electrical component.

3. The protective housing of claim 2, wherein the heat transfer element connects the heat coupling element and the cooling element.

4. The protective housing of claim 1, wherein the shell has a base and a side wall extending from the base.

5. The protective housing of claim 4, further comprising a notch disposed at an outer periphery of the base.

6. The protective housing of claim 5, wherein at least one of the first side plate and the second side plate is at least partly disposed in the notch.

7. The protective housing of claim 4, wherein the side wall has a first plug connected to a first cable.

8. The protective housing of claim 7, wherein the side wall has a second plug connected to a second cable.

9. The protective housing of claim 4, wherein the first side plate defines a portion of the first channel.

10. The protective housing of claim 9, wherein the cooling element forms a second channel that extends partly in the cover plate between opposing edges of the cooling element and increases a volume of the inner compartment.

11. The protective housing of claim 10, wherein the second side plate defines a portion of the second channel.

12. The protective housing of claim 11, wherein the side wall at least partly extends into the first channel and/or the second channel.

13. The protective housing of claim 1, wherein the cooling element is made of a material with a high thermal conductivity.

14. The protective housing of claim 1, wherein the cooling element has a coating which increases a thermal radiation of the cooling element.

15. The protective housing of claim 1, wherein the cooling element is formed by stamping and bending a single piece of a metal sheet.

16. The protective housing of claim 1, wherein the shell is formed by injection molding an electrically insulating material.

17. A method of assembling a power electronic unit, comprising:
providing a shell defining an inner compartment;
inserting an electrical component into the inner compartment;
providing a cooling element having a cover plate, a first side plate, and a second side plate, the first side plate and the second side plate extending from the cover plate, facing each other, and forming an inside surface, an outside surface, and edges of the cooling element;
covering the shell with at least a portion of the inside surface of the cooling element to form a cover of the inner compartment;
forming a channel in the cover plate that extends between opposing edges of the cooling element and increases a volume of the inner compartment;
cutting a cut-out in the cover plate; and
filling the inner compartment with an electrically insulating material through the cut-out in the cover plate and leaving a void in a portion of the channel.

18. The method of claim 17, further comprising providing a heat transfer element and a heat coupling element connected to the electrical component, the heat transfer element connecting the heat coupling element and the cooling element.
